(19) United States
(12) Patent Application Publication
(10) Pub. No.: US 2026/0143655 A1
(43) Pub. Date: May 21, 2026

(54) SYSTEMS FOR CLAMP FOR COOLING SYSTEM FOR INVERTER FOR ELECTRIC VEHICLE

(71) Applicant: BorgWarner Inc., Auburn Hills, MI (US)

(72) Inventors: Naga Venkata Ramya Sree VANKAMAMIDI, Westfield, IN (US); Mark Alan EBENHART, Kokomo, IN (US); Timothy R. FUNK, Indianapolis, IN (US)

(73) Assignee: BorgWarner Inc., Auburn Hills, MI (US)

(21) Appl. No.: 18/948,881

(22) Filed: Nov. 15, 2024

(51) Int. Cl. H05K 7/20

(52) U.S. Cl. CPC H05K 7/209; H05K 7/20445

(57) ABSTRACT

A clamp includes: a body including a first end and a second end, wherein the body extends along a longitudinal axis from the first end toward the second end; and a plurality of loading sources which extend below the body, wherein the plurality of loading sources include: a first loading source including a first fixed end and a first free end, the first loading source extending from the first fixed end toward the first free end; and a second loading source including a second fixed end and second free end, the second loading source extending from the second fixed end toward the second free end.

### TECHNICAL FIELD

Various embodiments of the present disclosure relate generally to systems that distribute thermal interface material (TIM) for dispensation of heat generated by a power source. More particularly, various embodiments of the present disclosure relate to clamps, for use in inverters for electric vehicles, which enable the distribution of thermal interface material (TIM) for dispensation of heat generated by a power source.

### BACKGROUND

A power module is considered a key component in a traction inverter to control the performance and efficiency of a driving system in an electric vehicle. Thermal management for a power module is therefore a critical aspect for performance and reliability of an electric vehicle. However, some thermal management methods for a double-sided cooled power module have limited capability for thermal performance optimization and low-cost manufacturability due to design and material selection. The present disclosure is directed to overcoming one or more of these above-referenced challenges.

### SUMMARY OF THE DISCLOSURE

In some aspects, the techniques described herein relate to a clamp including: a body including a first end and a second end, wherein the body extends along a longitudinal axis from the first end toward the second end; and a plurality of loading sources which extend below the body, wherein the plurality of loading sources include: a first loading source including a first fixed end and a first free end, the first loading source extending from the first fixed end toward the first free end, wherein the first fixed end is attached to the body, and the first free end is positioned at a first distance below the body, the first free end being positioned further away from the body than the first fixed end; and a second loading source including a second fixed end and second free end, the second loading source extending from the second fixed end toward the second free end, wherein the second fixed end is attached to the body, and the second free end is positioned at a second distance below the body, the second free end being positioned further away from the body than the second fixed end, wherein the first distance is greater than the second distance.

In some aspects, the techniques described herein relate to a clamp, wherein the body includes a first opening positioned at the first end of the longitudinal axis of the body, the first loading source extends from the first fixed end to the first free end into the first opening; and the second loading source extends from the second fixed end to the second free end into the first opening, wherein the first free end and the second free end extend toward one another.

In some aspects, the techniques described herein relate to a clamp, wherein the first loading source is located closer to the first end of the longitudinal axis of the body than the second loading source.

In some aspects, the techniques described herein relate to a clamp, wherein the first free end of the first loading source is spaced apart from the second free end of the second loading source within the first opening such that no material is disposed longitudinally between the first free end of the first loading source and the second free end of the second loading source.

In some aspects, the techniques described herein relate to a clamp, wherein the plurality of loading sources further include: a third loading source, including a third fixed end and a third free end, the third loading source extending from the third fixed end toward the third free end, wherein the third fixed end is attached to the body, and the third free end is positioned at the first distance below the body, the third free end being positioned further away from the body than the third fixed end; and a fourth loading source, including a fourth fixed end a fourth free end, the fourth loading source extending from the fourth fixed end toward the fourth free end, wherein the fourth fixed end is attached to the body, and the fourth free end is positioned at the second distance below the body, the fourth free end being positioned further away from the body than the fourth fixed end; the body includes a second opening positioned at the second end of the longitudinal axis of the body; the third loading source extends from the third fixed end to the third free end into the second opening; the fourth loading source extends from the fourth fixed end to the fourth free end into the second opening; wherein the third free end and the fourth free end extend toward one another; the third loading source is located closer to the second end of the longitudinal axis of the body than the fourth loading source; and the third free end and the fourth free end are spaced apart from one another within the second opening such that there is no material disposed longitudinally between.

In some aspects, the techniques described herein relate to a clamp,, wherein the plurality of loading sources further include: a fifth loading source, including a fifth fixed end and a fifth free end, the fifth loading source extending from the fifth fixed end toward the fifth free end, wherein the fifth fixed end of the fifth loading source is attached to the body, and the fifth free end of the fifth loading source is positioned at the second distance below the body, the fifth free end being positioned further away from the body than the fifth fixed end; and a sixth loading source including a sixth fixed end and a sixth free end, the sixth loading source extending from the sixth fixed end toward the sixth free end, wherein the sixth fixed end of the sixth loading source is attached to the body, and the sixth free end of the sixth loading source is positioned the second distance below the body, the sixth free end being positioned further away from the body than the sixth fixed end, wherein the fifth free end and sixth free are positioned at the second distance; the body has a third opening positioned between the first opening and the second opening and of the longitudinal axis of the body; the fifth loading source extends from the fifth fixed end to the fifth free end into the third opening; the sixth loading source extends from the sixth fixed end to the sixth free end into the third opening, wherein the fifth free end and the sixth free end extend toward one another; the fifth loading source is located closer to the first end of the longitudinal axis and the sixth loading source is located closer to the second end of the longitudinal axis; and the fifth free end and the sixth free end are spaced apart from one another within the third opening such that there is no material disposed longitudinally between.

In some aspects, the techniques described herein relate to a clamp, wherein the body has an exterior perimeter from which six arms extend below the body.

In some aspects, the techniques described herein relate to a clamp, wherein one of the six arms is positioned at the first end of the longitudinal axis of the body; one of the six arms is positioned at the second end of the longitudinal axis of the body; and four of the six arms are positioned around the exterior perimeter of the body, along the longitudinal axis, equally spaced from one another and the first end and the second end of the longitudinal axis.

In some aspects, the techniques described herein relate to a clamp, wherein the clamp is used in an assembly; the first loading source and the third loading source extending below the body to the first distance results in the first loading source and the third loading source applying a first force on the assembly; and the second loading source, the fourth loading source, the fifth loading source, and the sixth loading source extending below the body to the second distance results in the second loading source, the fourth loading source, the fifth loading source, and the sixth loading source applying a second force on the assembly, wherein the first force is greater than the second force.

In some aspects, the techniques described herein relate to an apparatus including: an electronic device extending along a longitudinal axis from a first end to a second end, the electronic device having a first heatsink and a second heatsink; and a clamp having a body extending along the longitudinal axis from the first end toward the second end and a plurality of loading sources which extend below the body and apply force onto the first heatsink at a plurality of loading surfaces, wherein the plurality of loading sources include: a first loading source including a first fixed end and a first free end, the first loading source extending from the first fixed end toward the first free end, wherein the first fixed end is attached to the body, and the first free end is positioned at a first distance below the body, the first free end being positioned further away from the body than the first fixed end, making contact and applying a first force at a first loading surface; and a second loading source including a second fixed end and a second free end, the second loading source extending from the second fixed end toward the second free end, wherein the second fixed end is attached to the body, and the second free end is at a second distance positioned below the body, the second free end being positioned further away from the body than the second fixed end, making contact and applying a second force at a second loading surface, wherein the first distance is greater than the second distance.

In some aspects, the techniques described herein relate to an apparatus, wherein the first force is greater than the second force.

In some aspects, the techniques described herein relate to an apparatus, wherein the body of the clamp has a first opening positioned at the first end of the longitudinal axis of the body, the first loading source extends from the first fixed end to the first free end into the first opening; and the second loading source extends from the second fixed end to the second free end into the first opening, wherein the first free end and the second free end extend toward one another.

In some aspects, the techniques described herein relate to an apparatus, wherein the first loading source of the clamp is located closer to the first end of the longitudinal axis of the body than the second loading source.

In some aspects, the techniques described herein relate to an apparatus, wherein the first free end of the first loading source of the clamp and the first free end of the second loading source of the clamp are spaced apart from one another within the first opening such that there is no material disposed longitudinally between.

In some aspects, the techniques described herein relate to an apparatus, wherein the plurality of loading sources further include: a third loading source including a third fixed end and a third free end, the third loading source extending from the third fixed end toward the third free end, wherein the third fixed end is attached to the body, and the third free end is positioned at the first distance below the body, the third free end being positioned further away from the body than the third fixed end, making contact at a third loading surface; and a fourth loading source including a fourth fixed end and a fourth free end, the fourth loading source extending from the fourth fixed end toward the fourth free end, wherein the fourth fixed end is attached to the body, and the fourth free end is positioned at the second distance below the body, the fourth free end being positioned further away from the body than the fourth fixed end, making contact at a fourth loading surface; the body has a second opening positioned at the second end of the longitudinal axis of the body; the third loading source extends from the third fixed end to the third free end into the second opening; the fourth loading source extends from the fourth fixed end to the fourth free end into the second opening, wherein the third free end and the fourth free end extend toward one another; the third loading source is located closer to the second end of the longitudinal axis of the body than the fourth loading source; and the third free end and the fourth free end are spaced apart from one another within the second opening such that there is no material disposed longitudinally between.

In some aspects, the techniques described herein relate to an apparatus, wherein: the third loading source applies the first force; and the second loading source applies the second force.

In some aspects, the techniques described herein relate to an apparatus, wherein the plurality of loading sources further include: a fifth loading source including a fifth fixed end and a fifth free end, the fifth loading source extending from the fifth fixed end toward the fifth free end, wherein the fifth fixed end is attached to the body, and the fifth free end is positioned at the second distance below the body, the fifth free end being positioned further away from the body than the fifth fixed end, making contact at a fifth loading surface; and a sixth loading source including a sixth fixed end and a sixth free end, the sixth loading source extending from the sixth fixed end toward the sixth free end, wherein the sixth fixed end is attached to the body, and the sixth free end is positioned the second distance below the body, the sixth free end being positioned further away from the body than the sixth fixed end, making contact at a sixth loading surface, wherein the fifth free end and the sixth free end are positioned at the second distance; the body has a third opening positioned between the first opening and the second opening of the longitudinal axis of the body; the fifth loading source extends from the fifth fixed end to the fifth free end into the third opening; the sixth loading source extends from the sixth fixed end to the sixth free end into the third opening, wherein the fifth free end and the sixth free end extend toward one another; the fifth loading source is located closer to the first end of the longitudinal axis and the sixth loading source is located closer to the second end of the longitudinal axis; and the fifth free end and the sixth free end are spaced apart from one another within the third opening such that there is no material disposed longitudinally between.

In some aspects, the techniques described herein relate to an apparatus, wherein the fifth loading source and the sixth loading source apply the second force.

In some aspects, the techniques described herein relate to an apparatus, wherein the body has an exterior perimeter from which six arms extend below the body.

In some aspects, the techniques described herein relate to an apparatus, wherein one of the six arms is positioned at the first end of the longitudinal axis of the body; one of the six arms is positioned at the second end of the longitudinal axis of the body; and four of the six arms are positioned around the exterior perimeter of the body, along the longitudinal axis, equally spaced from one another and the first end and the second end of the longitudinal axis.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 depicts an exemplary system infrastructure for a vehicle including an inverter, according to one or more embodiments.

FIG. 2 depicts an exemplary system infrastructure for the inverter of FIG. 1, according to one or more embodiments.

FIG. 3 depicts an isometric view of an exemplary power module assembly, according to one of more embodiments.

FIG. 4 depicts an exploded view of an exemplary power module assembly, according to one or more embodiments.

FIG. 5 depicts an isometric view of the clamp depicted in the exemplary power module assembly of FIG. 3, according to one or more embodiments.

FIG. 6 depicts a planar view of the clamp depicted in the exemplary power module assembly of FIG. 3, according to one or more embodiments.

FIG. 7 depicts a distribution of thermal interface material (TIM) on first and second heatsinks, according to one or more embodiments.

### DETAILED DESCRIPTION OF EMBODIMENTS

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value. In this disclosure, unless stated otherwise, any numeric value may include a possible variation of ±10% in the stated value.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. For example, in the context of the disclosure, the switching devices may be described as switches or devices, but may refer to any device for controlling the flow of power in an electrical circuit. For example, switches may be metal-oxide- semiconductor field-effect transistors (MOSFETs), bipolar junction transistors (BJTs), insulated-gate bipolar transistors (IGBTs), or relays, for example, or any combination thereof, but are not limited thereto.

Various embodiments of the present disclosure relate generally to systems that distribute thermal interface material (TIM) for dispensation of heat generated by a power source. Types of thermal interface materials may include, but are not limited to, pads, greases, thermal compounds, gels, thermal adhesives, epoxy, phase change materials, pyrolytic graphite, or derivates thereof.

More particularly, various embodiments of the present disclosure relate to clamps, for use in inverters for electric vehicles, which enable the distribution of thermal interface material (TIM) for dispensation of heat generated by a power source. However, the present disclosure is not so limited, and the embodiments described herein are provided for use in any appropriate mechanical system. For example, various embodiments of the present disclosure may relate to varying load clamps in a mechanical system.

Inverters, such as those used to drive a motor in an electric vehicle, for example, are responsible for converting High Voltage Direct Current (HVDC) into Alternating Current (AC) to drive the motor. A three phase inverter may include a bridge with six power device switches (for example, power transistors such as IGBT or MOSFET) that are controlled by Pulse Width Modulation (PWM) signals generated by a controller.

A power module assembly for an inverter, such as those discussed above, may incorporate a cooling system that may include two active heatsinks on either side (e.g., opposing top and bottom sides) of one or more electrical components, such as power modules. An active heatsink may be a heatsink having components (e.g., fins or compartments) through which a coolant material flows. For simplicity, this disclosure references electrical components as power modules, substrates, printed circuit boards (PCBs), and combinations thereof, though it will be understood that the techniques disclosed herein may apply to any electrical component (e.g., power switches, chips, chip components, controllers, etc.) that may generate heat. According to one or more embodiments, a power module assembly may include two active heatsinks. These heatsinks may provide thermal dissipation by drawing heat away from one or more dies, referred to as power switches, towards a surface area of a power module, and further towards portions of the active heatsink that make direct or indirect contact with a cooling medium, e.g., coolant or air, associated with the active heatsinks.

Heatsinks may dissipate heat by thermally conducting heat into a fluid medium, often via a utilization of Thermal Interface Material (TIM) for improved heat transfer capability between the heat source and heatsink. Automotive cooling systems, for example, often use one or more heatsinks to dissipate heat from power modules, such as those employed in electric vehicles. Even though system performance needs requiring lower thermal resistance continue to rise, such as the needs in the electric vehicle industry, performance capabilities of various electrical components, such as power modules generally, power modules for inverters, and inverters generally, remain limited by cooling capabilities of conventional heat dissipation components. In addition to the issues related to cooling, securing in place heat dissipation components, such as active heatsinks, may be complex, and current solutions provide poor force distribution onto electrical components.

In some electrical components that include multiple power modules, clamps may be used to provide pressure to spread or reflow (i.e. compress) TIM over the respective lifetimes of these components. However, these configurations of clamps do not adequately account for design complexity, material expenses, and risk of coolant leaks involved in heatsink use. In particular, the use of such clamps, which may be complex in configuration and implementation, may provide loading at locations where seals connecting the top and second heatsinks are present. Loading at these locations that does not account for the opposing force of the seals result in the inadequate compression of TIM and loss of cooling capacity. Such problems risk rendering the types of electrical components with multiple power modules, and those components electrically connected thereto, inoperable or sub-operable due to such issues or resultant electrical component damage.

Some designs do not provide equal pressure at all power switch locations, resulting in varying thermal performance between switches. Some power modules require multiple “C” clamps to secure the two halves of the heatsink. Each clamp in the assembly applies the same force at all locations; so the resultant force on the TIM (thermal interface material) is highly dependent on position and location of the clamp on the heatsink. Proper TIM material spread is critical in achieving optimal heat transfer performance between the power switch and heatsink. Initial thermal performance is typically worse on the two outer switches due to uneven spreading of the TIM material. The outer “C” clamps must provide enough force to compress the coolant seals and spread the TIM during phase change. Center clamps only need to provide the force required to spread the TIM during phase change. This results in uneven pressure and thus uneven spreading of the TIM during phase change. Some designs reduce thermal variation by adding a plate on top of the power module that applies pressure on the assembly line. The clamps by themselves, in particular the outside clamps, may not provide enough pressure to spread the TIM properly during reflow. The c-clamps (or clips) require additional parts, screws, bushings, and bracket(s), to hold them in place in the assembly. This further complicates the assembly process with added processes and parts.

Further, use of “C” clamps for securing the two halves of the heatsink fails to account for variations in the thickness of the power modules. In the event each power module varies in thickness and the clamp is planar, the result is uneven pressure and uneven spreading of the TIM.

The heat rail clamp aids with the heat transfer component of the power module assembly, which is a critical element of the inverter system, by ensuring optimal spread of the thermal interface material is achieved while holding the components of the sub-assembly together. One or more embodiments may provide a system to provide varying clamp load distribution across the length of the heatsink surface, by adjusting the interference or the distance from the load surface to clip location as calculated in each area of interest and using the tensile and reaction forces on the clamp for loading, so that proper TIM spread is achieved. One or more embodiments may provide a system where no additional mounting methods are required, as the clamp directly clips on to the heatsink holding an assembly of parts (e.g., seven parts) together, which is unlike the c-clip which requires additional mounting screws, bushings, and the cradle to mount onto the housing.

One or more embodiments may provide a heatsink clamp with modularity in design. One or more embodiments may provide a heatsink clamp that replaces the C-clip (being used in 8 locations in a single assembly when placed in the housing) with a single clamp, and thereby making the heatsink assembly modular. One or more embodiments may provide a heatsink clamp with variable load distribution by adjusting/varying the interference/displacement on the clamp pressure tabs/loading surfaces calculated in certain areas where higher forces are needed (such as the locations close to heatsink seals to overcome seal forces for compression), which may provide increased pressure distribution in all areas. One or more embodiments may provide a heatsink clamp with seal compression. The variable load clamp may provide additional compressive forces required to overcome the seal reaction forces and compress the seals. The interference in these areas may be adjusted as needed based on the seal material, geometry, and stack up. One or more embodiments may provide a heatsink clamp with pressure tabs. The clamp design is engineered to press down on the heatsink in critical locations such that proper TIM spread is obtained by controlled clamping force, which utilizes tensile and spring reaction forces for pressing down. One or more embodiments may provide a heatsink clamp with question mark legs: The question mark legs on the clamp may provide stress relief in the assembly process, avoiding any buckling failure. These legs partly contribute to the even pressure distribution across the different stack-ups. One or more embodiments may provide a heatsink clamp with a reduced TIM size to reduce overall cost.

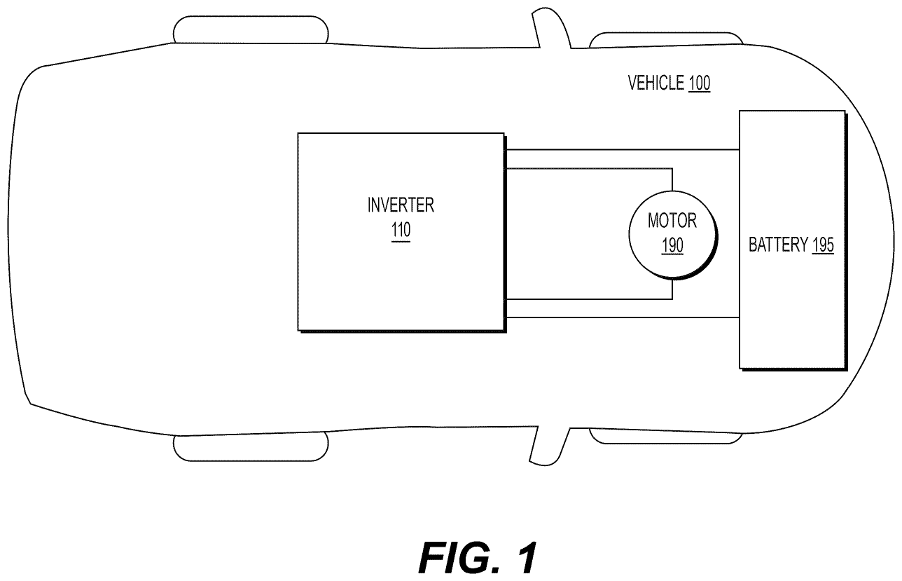

FIG. 1 depicts an exemplary system infrastructure for a vehicle including an inverter, according to one or more embodiments. As shown in FIG. 1, electric vehicle 100 may include an inverter 110, a motor 190, and a battery 195. The inverter 110 may include components to receive electrical power from an external source and output electrical power to charge battery 195 of electric vehicle 100. The inverter 110 may convert DC power from battery 195 in electric vehicle 100 to AC power, to drive motor 190 of the electric vehicle 100, for example, but the embodiments are not limited thereto. The inverter 110 may be bidirectional, and may convert DC power to AC power, or convert AC power to DC power, such as during regenerative braking, for example. Inverter 110 may be a three-phase inverter, a single-phase inverter, or a multi-phase inverter.

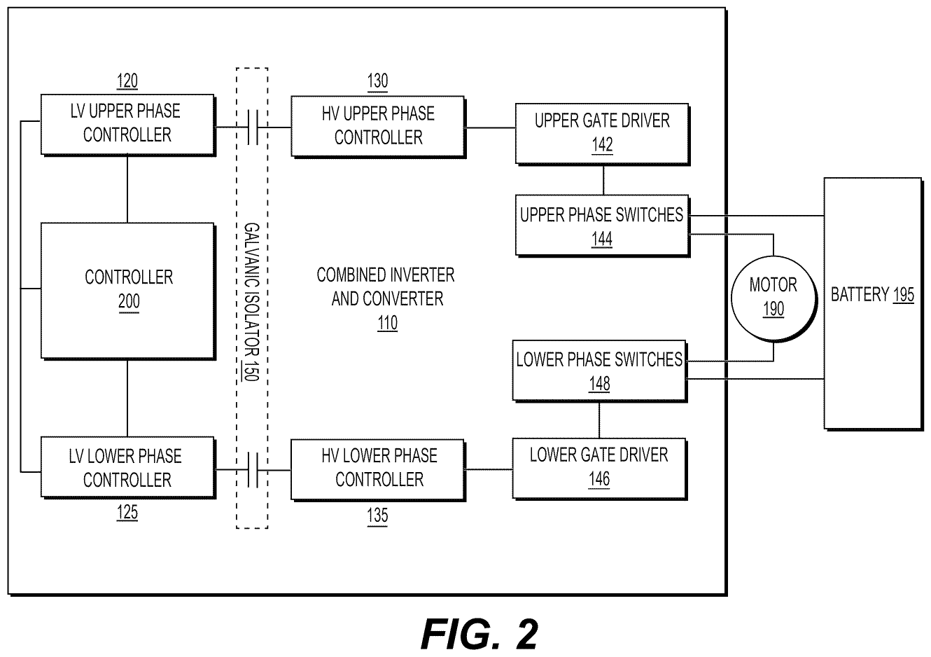

FIG. 2 depicts an exemplary system infrastructure for the combined inverter and converter of FIG. 1, according to one or more embodiments. Inverter 110 may include an inverter controller 200 to control the inverter 110. Inverter 110 may include a low voltage upper phase controller 120 separated from a high voltage upper phase controller 130 by a galvanic isolator 150. Inverter 110 may include a low voltage lower phase controller 125 separated from a high voltage lower phase controller 135 by galvanic isolator 150. Inverter 110 may include a high voltage upper phase controller 130 including a gate driver power supply, an upper gate driver 142, and upper phase switches 144. Inverter 110 may include a high voltage lower phase controller 135 including a gate drive power supply, a lower gate driver 146, and lower phase switches 148. Upper phase switches 144 and lower phase switches 148 may be connected to motor 190 and battery 195. Galvanic isolator 150 may be one or more of optical, transformer-based, or capacitance-based isolation, but embodiments are not limited thereto. Galvanic isolator 150 may be one or more capacitors with a value from approximately 20 fF to approximately 100 fF, with a breakdown voltage from approximately 6 kV to approximately 12 kV, for example, but embodiments are not limited thereto. Galvanic isolator 150 may include a pair of capacitors, where one capacitor of the pair carries an inverse data signal from the other capacitor of the pair to create a differential signal for common-mode noise rejection. Galvanic isolator 150 may include more than one capacitor in series. Galvanic isolator 150 may include one capacitor located on a first IC, or may include a first capacitor located on a first IC and a second capacitor located on a second IC that communicates with the first IC.

Inverter 110 may include a low voltage area, where voltages are generally less than 5V, for example, and a high voltage area, where voltages may exceed 500V, for example. The low voltage area may be separated from the high voltage area by galvanic isolator 150. Inverter controller 200 may be in the low voltage area of inverter 110, and may send signals to and receive signals from low voltage upper phase controller 120. Low voltage upper phase controller 120 may be in the low voltage area of inverter 110, and may send signals to and receive signals from high voltage upper phase controller 130. Low voltage upper phase controller 120 may send signals to and receive signals from low voltage lower phase controller 125. High voltage upper phase controller 130 may be in the high voltage area of inverter 110. Accordingly, signals between low voltage upper phase controller 120 and high voltage upper phase controller 130 pass through galvanic isolator 150. High voltage upper phase controller 130 may send signals to and receive signals from the upper gate driver 142. The upper gate driver 142 may send signals to and receive signals from the upper phase switches 144. Upper phase switches 144 may be connected to motor 190 and battery 195. Upper phase switches 144 and lower phase switches 148 may be used to transfer energy from motor 190 to battery 195, from battery 195 to motor 190, from an external source to battery 195, or from battery 195 to an external source, for example. The lower phase system of inverter 110 may be similar to the upper phase system as described above.

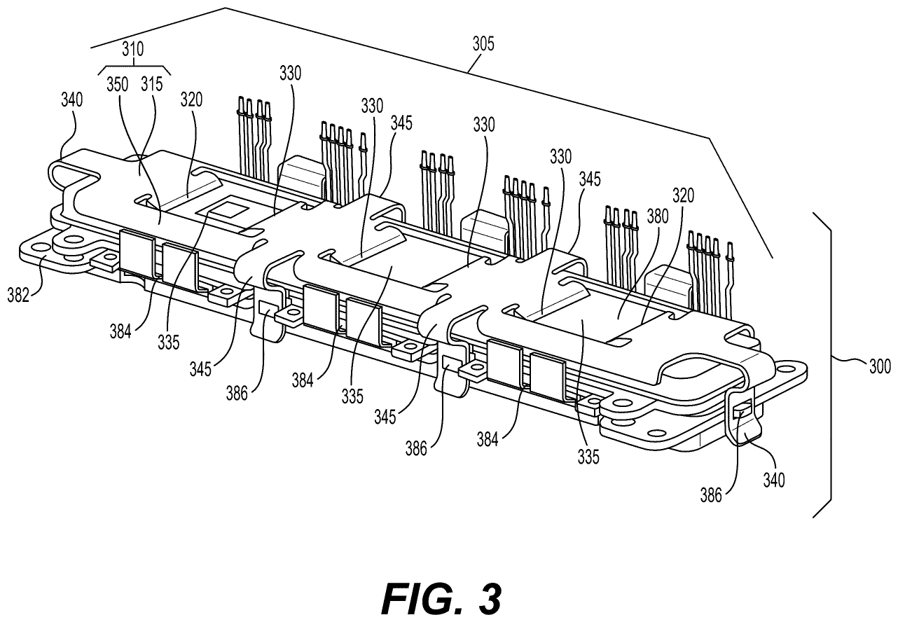

FIG. 3 depicts an isometric view of an electronic device according to one or more embodiments. The electronic device may be a power module assembly 300 which includes power modules 384 that are integrated into an exemplary cooling system having a first heatsink 380 and second heatsink 382. Power modules 384 may include multiple power switches. The power module assembly 300 may extend from a first end to a second end of a longitudinal axis. The cooling system may include a first heatsink 380 and second heatsink 382 held in position relative to the power modules 384 (e.g., above and below, or otherwise on opposing sides of the power modules 384) by clamp 305. The clamp 305 may extend across the entirety of the power module assembly 300. As shown, the clamp 305 may be configured to attach the power modules 384, the first (i.e. top) heatsink 380 and second (i.e. bottom) heatsink 382 without the need for any additional mounting methods or additional tools.

One of ordinary skill in the art will recognize the cooling system depicted in FIG. 3, including the first heatsink 380 and the second heatsink 382, is an exemplary cooling system. According to the present disclosure, a cooling system that may be incorporated into the power module assemblies described herein may include one heatsink, two heatsinks, may employ one-sided active or passive cooling, double-sided active cooling, double-sided passive cooling, or double-sided cooling provided by one active cooling component and one passive cooling component.

The clamp 305 may include a body 310 having a flat span 315 and shoulders 350. The flat span 315 may run above and parallel to the first heatsink 380 along the same longitudinal axis. The flat span 315 may be interrupted by holes or openings 335 having no material disposed along the longitudinal axis therein, apart from shoulders 350 which run along the exterior perimeter of the clamp 305 and maintain the structure of the body 310 along the length of each opening 335. The outer edges of the flat span 315 and shoulders 350 constitute the exterior perimeter of the clamp 305. Clamp 305 may have three openings 335. One of ordinary skill in the art will recognize the clamp 305 depicted in FIG. 3 including three openings is merely one embodiment contained within the disclosure. According to the present disclosure, clamp 305 may include one or more openings depending on the requirements of any individual power module assembly.

At each opening 335, the flat span 315 may be connected to cantilever shaped loading sources 320 and 330 which extend into the openings 335 and make contact with the underlying first heatsink 380. The flat span 315 does not otherwise make contact with the power module assembly 300. Loading sources 320 and loading sources 330 extend from an end fixed (i.e. fixed end) to the flat span 315 of the body 310 to a free-floating free end. Each longitudinal end of an opening 335 may be connected to the fixed end of either (1) one of loading sources 320 and one of loading sources 330 or (2) two of loading sources 330. The result is that in that in each opening 335, either one of loading sources 320 and loading sources 330 or two of loading sources 330, are spaced apart from, extend toward, and face one another across the opening 335. No opening 335 has more than two loading sources contained therein.

Loading sources 320 and loading sources 330 may be configured as cantilevers having a roughly S-shape. As shown, the body 310 may have two loadings sources 320 and four loading sources 330, each extending from a fixed end to a free end. One of ordinary skill in the art will recognize the clamp 305 depicted in FIG. 3 including six loading sources is exemplary and other embodiments are encompassed by the disclosure. According to the present disclosure, clamp 305 may have more or fewer than six loading sources depending on the requirements of any individual power module assembly.

The free ends of loading sources 320 and loading sources 330 extend into openings 335 and terminate at a distance below the flat span 315. The free ends of loading sources 320 and loading sources 330 make contact with the surface of the underlying first heatsink 380 at discrete locations (i.e. loading surfaces). In one embodiment, the free ends of loading sources 320 and loading sources 330 terminate at different distances 6A, 6B below the flat span 315. Distance 6A may be at a distance further below a plane relative to the flat span 315 than distance 6B.

As shown in FIG. 3, there are three discrete loading zones along the longitudinal axis of clamp 305. The first loading zone may be located at the first end of the longitudinal axis of clamp 305 and may contain the first and second loading surfaces. The first loading zone roughly corresponds to opening 335 located at the first end of the longitudinal axis of clamp 305. Loading sources 320 and loading sources 330 are located at the first loading zone where they make contact with the first and second loading surfaces. Loading source 320 may be located closer to the first end of the longitudinal axis than loading source 330.

The second loading zone may be located at the second end of the longitudinal axis of clamp 305 and may contain the third and fourth loading surfaces. Similarly, loading sources 320 and loading sources 330 are located at the second loading zone where they make contact with the third and fourth loading surfaces. The second loading zone roughly corresponds to opening 335 located at the second end of the longitudinal axis of clamp 305. Loading source 320 may be located closer to the second end of the longitudinal axis than loading source 330. The placement of loading sources 320 and 330 in the first and second loading zones are the mirror image of one another on opposite sides of the lateral axis at the center of the longitudinal axis of clamp 305.

The third loading zone may be located in the middle of the longitudinal axis of clamp 305, between the first and second loading zones. The third loading zone may contain the fifth and sixth loading surfaces. Loading sources 330 are located at the third loading zone where they make contact with the fifth and sixth loading surfaces. Loading sources 330 in the first, second, and third loading zones may extend the same distance below the flat span 315 as one another. Loading source 320 in the first loading zone may extend the same distance as loading source 320 in the second loading zone. Loading sources 320 may extend a greater distance than loading sources 330 below flat span 315. Loading sources 320 apply greater force than loading sources 330.

Advantages described in the disclosure include that clamp 305 is a modular device and may hold the power module assembly 300 without the need of additional mounting methods or tools. The clamp 305 results in greater force being applied at the first and second ends of the longitudinal access of the power module assembly 300 than along a center of power module assembly 300. This allows for clamp 305 to apply adequate force at the first and second ends to overcome any opposing forces generated by subcomponents of the assembly, ensuring the sufficient flow of coolant in the cooling system between the first heatsink 380 and second heatsink 382.

The clamp 305 may include arms 340 and arms 345 connected to the body 310. Arms 340 and arms 345 are located around the exterior of clamp 305. Each of arms 340 and arms 345 may be in the shape of a hook, ultimately extending away from and below the flat span 315 of the clamp 305 at an approximately right angle relative to plane corresponding to the flat span 315, culminating in a terminal end. Advantages of arms 340 and arms 345 having a hook shape include ensuring there is stress relief in the assembly process, avoiding any buckling failure. The disclosure is not however limited to arms having any particular shape.

Each arm 340 and arm 345 may contain a hole located in its terminal end. The holes in each arm 340 and arm 345 may receive a notch 386 protruding from the second heatsink 382. Mating the hole in each arm 340 and arm 345 with a notch 386 protruding from the second heatsink 382 allows the clamp 305 to hold the first heatsink 380, power modules 384, and second heatsink 382 together without the need for any additional mounting methods or tools. One of ordinary skill in the art will recognize that securing clamp 305 depicted in FIG. 3 is an exemplary clamp, and the disclosure is not limited thereto.

As shown in one exemplary configuration, the clamp 305 may be configured to have six arms, but the disclosure is not limited to any specific number of arms. Arms 340 are located at the first end and the second end of the longitudinal axis along the exterior of the power module assembly 300. Arms 345 are placed along the side of the longitudinal axis of the power module assembly, around its exterior perimeter. Four of arms 345 are placed so that each one forms a pair with another arm 345 having the same lateral position on the opposite side of the longitudinal axis. One pair of arms 345 may be placed closer to the first end of the longitudinal axis while the other pair of arms 345 may be placed closer to the second end of the longitudinal axis. Each pair of arms 345 may sit in between (1) the first and third loading zone and (2) the second and third loading zone along the longitudinal axis of the power module assembly.

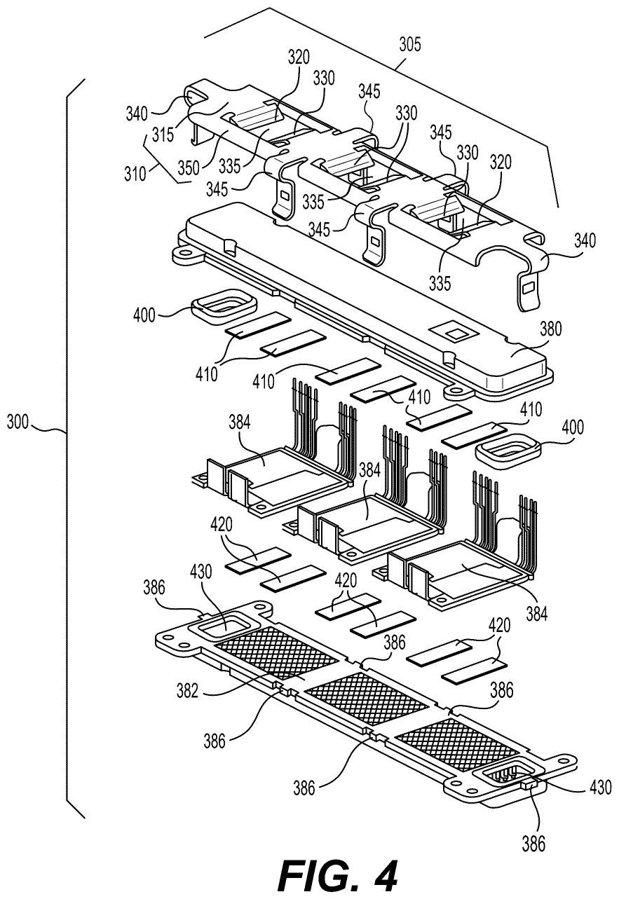

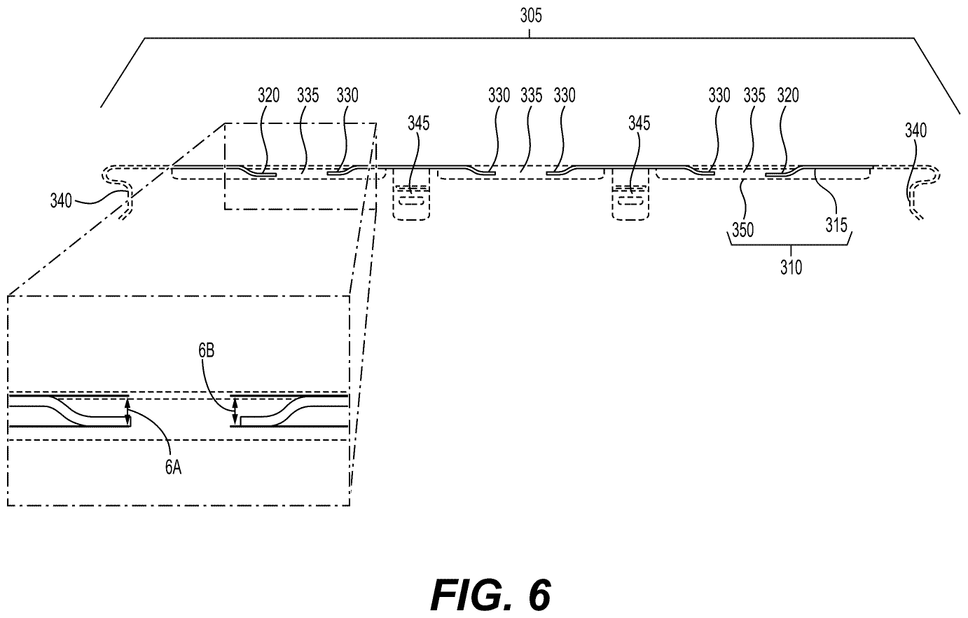

FIG. 4 depicts an exploded view of an exemplary power module assembly 300 of FIG. 3. As shown, in addition to the clamp 305, first heatsink 380, power modules 384, and second heatsink 382, the power module assembly 300 includes thermal interface material (TIM) 410, TIM 420, and seals 400. TIM 410 and TIM 420 provide for improved heat transfer capability from the power modules 384 to the first heatsink 380 and second heatsink 382. TIM 410 is provided between the power modules 384 and the first heatsink 380. TIM 420 is provided between the power modules 384 and the second heatsink 382. The first heatsink 380 and second heatsink 382 include ports 430 and 435 (see FIG. 6) which allow for the free flow of coolant. Seals 400 are placed between the ports 430 and 435 to avoid leaking of coolant during operation of the cooling system including first heatsink 380 and second heatsink 382.

That is, coolant may pass from the first end of the power module assembly 300 to the second end through both of the first heatsink 380 and second heatsink 382. At either the first and second end of the power module assembly 300, port 430 on the second heatsink 382, seal 400, and port 435 on the first heatsink 380 defines an inlet flow path for the cooling system including the first heatsink 380 and second heatsink 382. The port 435 on the first heatsink 380, seal 400, and port 430 on the second heatsink 382 located at the opposite end of the power module assembly 300 defines an outlet flow path for the cooling system including first heatsink 380 and second heatsink 382. The disclosure is not limited as to whether coolant enters the cooling system including first heatsink 380 and second heatsink 382 at either the first or second end of the power module assembly 300.

One of ports 435 of the first heatsink 380 serves as both: (1) an inlet for coolant to enter and flow longitudinally through the first heatsink 380, and (2) an outlet or first through port for coolant flowing vertically through the first heatsink 380 and on to the second heatsink 382. Similarly, the other port 435 of the first heatsink 380 provides both (1) an outlet for coolant flowing longitudinally through the first heatsink 380, and (2) an inlet or second through port for coolant from the second port 430 of the second heatsink 382. The disclosure is not limited as to which port 435 serves as an inlet or outlet for coolant in respect to the second heatsink 382. The coolant flows from the second heatsink 382 having traversed through a plurality of channels extending within the second heatsink 382 along a longitudinal axis of the power module assembly 300.

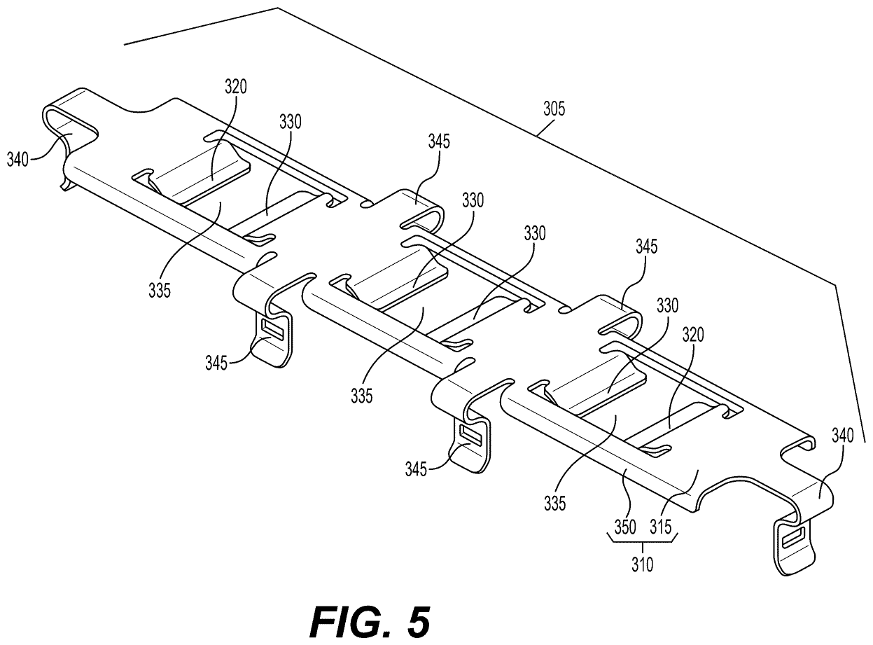

FIG. 5 depicts an isometric view of the clamp 305 in the absence of the rest of the components of the exemplary power module assembly 300 of FIG. 3. The clamp 305 may be configured as a modular device separate from the rest of the power module assembly 300. Advantages of the modular design of the clamp 305 include: (1) holding the power module assembly 300 together without the need for any other mounting methods or tools; and (2) providing adequate compressive loading onto the power module assembly 300 to equally distribute TIM 410 and 420 between the power modules 384 and the first heatsink 380 and second heatsink 382.

FIG. 6 depicts a planar view of clamp 305 while providing a magnified view of loading sources 320 and loading sources 330. As shown, the free end of loading sources 320 may extend below a plane corresponding to the flat span 315 of the body 310, terminating at a distance 6A below such a plane. Similarly, the free end of loading source 330 may extend below a plane corresponding to the flat span 315 of body 310, terminating at a distance 6B below such a plane. Distances 6A and 6B may be any length from approximately 0.1 mm to approximately 5 mm so long as distance 6A is greater than 6B. In one embodiment, distance 6A is 2 mm and distance 6B is 1.5 mm, although the disclosure described herein is not so limited.

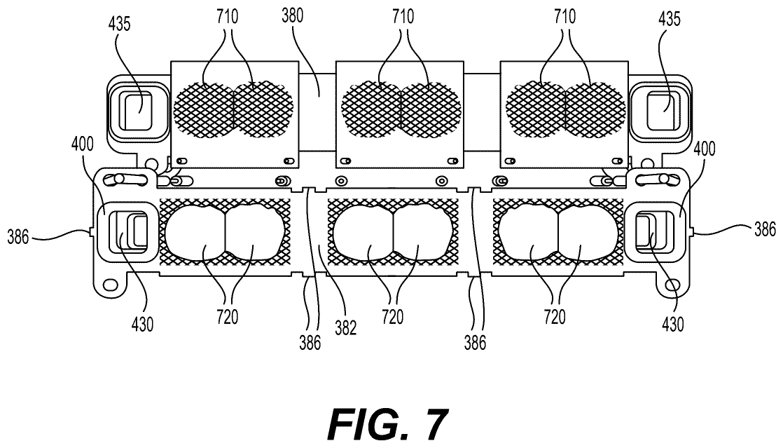

FIG. 7 depicts the even distribution of TIM 710 and 720 on the first heatsink 380 and second heatsink 382, respectively, resulting from the use of clamp 305 in the power module assembly 300. TIM 710 and 720 result from compressing TIM 410 and 420, respectively. Loading sources 320 provide greater compressive force than loading sources 330, resulting in greater compressive forces being applied at the first and second end of the longitudinal axis of the power module assembly 300 than in its center. As shown, the greater compressive forces applied at the first and second ends of the power module assembly 300 by loading sources 320 results in even distribution of TIM 710 and 720 providing for more efficient heat dissipation across the power module assembly 300. Loading sources 320 overcome the opposing forces generated by the seals 400, allowing the clamp 305 to provide adequate compressive force resulting in evenly distributed TIM 710, 720.

One or more embodiments may provide a system to provide varying clamp load distribution across the length of the heatsink surface, by adjusting the interference or the distance from the load surface to clip location as calculated in each area of interest and using the tensile and reaction forces on the clamp for loading, so that proper TIM spread may be achieved. One or more embodiments may provide a system where no additional mounting methods are required, as the clamp directly clips on to the heatsink holding an assembly of parts (e.g., seven parts) together, which is unlike the c-clip which requires additional mounting screws, bushings, and the cradle to mount onto the housing.

One or more embodiments may provide a heatsink clamp with modularity in design. One or more embodiments may provide a heatsink clamp that replaces the C-clip (being used in 8 locations in a single assembly when placed in the housing) with a single clamp, and thereby making the heatsink assembly modular. One or more embodiments may provide a heatsink clamp with variable load distribution by adjusting/varying the interference/displacement on the clamp pressure tabs/loading surfaces calculated in certain areas where higher forces are needed (such as the locations close to heatsink seals to overcome seal forces for compression), which may provide increased pressure distribution in all areas. One or more embodiments may provide a heatsink clamp with seal compression. The variable load clamp may provide additional compressive forces required to overcome the seal reaction forces and compress the seals. The interference in these areas may be adjusted as needed based on the seal material, geometry, and stack up. One or more embodiments may provide a heatsink clamp with pressure tabs. The clamp design is engineered to press down on the heatsink in critical locations such that proper TIM spread is obtained by controlled clamping force, which utilizes tensile and spring reaction forces for pressing down. One or more embodiments may provide a heatsink clamp with question mark legs: The question mark legs on the clamp may provide stress relief in the assembly process, avoiding any buckling failure. These legs partly contribute to the even pressure distribution across the different stack-ups. One or more embodiments may provide a heatsink clamp with a reduced TIM pad size to reduce overall cost.

Other embodiments of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

What is claimed is:

1. A clamp comprising:
a body including a first end and a second end, wherein the body extends along a longitudinal axis from the first end toward the second end; and
a plurality of loading sources which extend below the body, wherein the plurality of loading sources include:
a first loading source including a first fixed end and a first free end, the first loading source extending from the first fixed end toward the first free end, wherein the first fixed end is attached to the body, and the first free end is positioned at a first distance below the body, the first free end being positioned further away from the body than the first fixed end; and
a second loading source including a second fixed end and second free end, the second loading source extending from the second fixed end toward the second free end, wherein the second fixed end is attached to the body, and the second free end is positioned at a second distance below the body, the second free end being positioned further away from the body than the second fixed end, wherein the first distance is greater than the second distance.

2. The clamp of claim 1, wherein the body includes a first opening positioned at the first end of the longitudinal axis of the body,
the first loading source extends from the first fixed end to the first free end into the first opening; and
the second loading source extends from the second fixed end to the second free end into the first opening, wherein the first free end and the second free end extend toward one another.

3. The clamp of claim 2, wherein the first loading source is located closer to the first end of the longitudinal axis of the body than the second loading source.

4. The clamp of claim 3, wherein the first free end of the first loading source is spaced apart from the second free end of the second loading source within the first opening such that no material is disposed longitudinally between the first free end of the first loading source and the second free end of the second loading source.

5. The clamp of claim 4, wherein the plurality of loading sources further include:
a third loading source, including a third fixed end and a third free end, the third loading source extending from the third fixed end toward the third free end, wherein the third fixed end is attached to the body, and the third free end is positioned at the first distance below the body, the third free end being positioned further away from the body than the third fixed end; and
a fourth loading source, including a fourth fixed end a fourth free end, the fourth loading source extending from the fourth fixed end toward the fourth free end, wherein the fourth fixed end is attached to the body, and the fourth free end is positioned at the second distance below the body, the fourth free end being positioned further away from the body than the fourth fixed end;
the body includes a second opening positioned at the second end of the longitudinal axis of the body;
the third loading source extends from the third fixed end to the third free end into the second opening;
the fourth loading source extends from the fourth fixed end to the fourth free end into the second opening; wherein the third free end and the fourth free end extend toward one another;
the third loading source is located closer to the second end of the longitudinal axis of the body than the fourth loading source; and
the third free end and the fourth free end are spaced apart from one another within the second opening such that there is no material disposed longitudinally between.

6. The clamp of claim 5,, wherein the plurality of loading sources further include:
a fifth loading source, including a fifth fixed end and a fifth free end, the fifth loading source extending from the fifth fixed end toward the fifth free end, wherein the fifth fixed end of the fifth loading source is attached to the body, and the fifth free end of the fifth loading source is positioned at the second distance below the body, the fifth free end being positioned further away from the body than the fifth fixed end; and
a sixth loading source including a sixth fixed end and a sixth free end, the sixth loading source extending from the sixth fixed end toward the sixth free end, wherein the sixth fixed end of the sixth loading source is attached to the body, and the sixth free end of the sixth loading source is positioned the second distance below the body, the sixth free end being positioned further away from the body than the sixth fixed end, wherein the fifth free end and sixth free are positioned at the second distance;
the body has a third opening positioned between the first opening and the second opening and of the longitudinal axis of the body;
the fifth loading source extends from the fifth fixed end to the fifth free end into the third opening;
the sixth loading source extends from the sixth fixed end to the sixth free end into the third opening, wherein the fifth free end and the sixth free end extend toward one another;
the fifth loading source is located closer to the first end of the longitudinal axis and the sixth loading source is located closer to the second end of the longitudinal axis; and
the fifth free end and the sixth free end are spaced apart from one another within the third opening such that there is no material disposed longitudinally between.

7. The clamp of claim 6, wherein the body has an exterior perimeter from which six arms extend below the body.

8. The clamp of claim 7, wherein one of the six arms is positioned at the first end of the longitudinal axis of the body; one of the six arms is positioned at the second end of the longitudinal axis of the body; and four of the six arms are positioned around the exterior perimeter of the body, along the longitudinal axis, equally spaced from one another and the first end and the second end of the longitudinal axis.

9. The clamp of claim 6, wherein the clamp is used in an assembly;
the first loading source and the third loading source extending below the body to the first distance results in the first loading source and the third loading source applying a first force on the assembly; and
the second loading source, the fourth loading source, the fifth loading source, and the sixth loading source extending below the body to the second distance results in the second loading source, the fourth loading source, the fifth loading source, and the sixth loading source applying a second force on the assembly, wherein the first force is greater than the second force.

10. An apparatus comprising:
an electronic device extending along a longitudinal axis from a first end to a second end, the electronic device having a first heatsink and a second heatsink; and
a clamp having a body extending along the longitudinal axis from the first end toward the second end and a plurality of loading sources which extend below the body and apply force onto the first heatsink at a plurality of loading surfaces, wherein the plurality of loading sources include:
a first loading source including a first fixed end and a first free end, the first loading source extending from the first fixed end toward the first free end, wherein the first fixed end is attached to the body, and the first free end is positioned at a first distance below the body, the first free end being positioned further away from the body than the first fixed end, making contact and applying a first force at a first loading surface; and
a second loading source including a second fixed end and a second free end, the second loading source extending from the second fixed end toward the second free end, wherein the second fixed end is attached to the body, and the second free end is at a second distance positioned below the body, the second free end being positioned further away from the body than the second fixed end, making contact and applying a second force at a second loading surface, wherein the first distance is greater than the second distance.

11. The apparatus of claim 10, wherein the first force is greater than the second force.

12. The apparatus of claim 11, wherein the body of the clamp has a first opening positioned at the first end of the longitudinal axis of the body,
the first loading source extends from the first fixed end to the first free end into the first opening; and
the second loading source extends from the second fixed end to the second free end into the first opening, wherein the first free end and the second free end extend toward one another.

13. The apparatus of claim 12, wherein the first loading source of the clamp is located closer to the first end of the longitudinal axis of the body than the second loading source.

14. The apparatus of claim 13, wherein the first free end of the first loading source of the clamp and the first free end of the second loading source of the clamp are spaced apart from one another within the first opening such that there is no material disposed longitudinally between.

15. The apparatus of claim 14, wherein the plurality of loading sources further include:
a third loading source including a third fixed end and a third free end, the third loading source extending from the third fixed end toward the third free end, wherein the third fixed end is attached to the body, and the third free end is positioned at the first distance below the body, the third free end being positioned further away from the body than the third fixed end, making contact at a third loading surface; and
a fourth loading source including a fourth fixed end and a fourth free end, the fourth loading source extending from the fourth fixed end toward the fourth free end, wherein the fourth fixed end is attached to the body, and the fourth free end is positioned at the second distance below the body, the fourth free end being positioned further away from the body than the fourth fixed end, making contact at a fourth loading surface;
the body has a second opening positioned at the second end of the longitudinal axis of the body;
the third loading source extends from the third fixed end to the third free end into the second opening;
the fourth loading source extends from the fourth fixed end to the fourth free end into the second opening, wherein the third free end and the fourth free end extend toward one another;
the third loading source is located closer to the second end of the longitudinal axis of the body than the fourth loading source; and
the third free end and the fourth free end are spaced apart from one another within the second opening such that there is no material disposed longitudinally between.

16. The apparatus of claim 15, wherein:
the third loading source applies the first force; and
the second loading source applies the second force.

17. The apparatus of claim 16, wherein the plurality of loading sources further include:
a fifth loading source including a fifth fixed end and a fifth free end, the fifth loading source extending from the fifth fixed end toward the fifth free end, wherein the fifth fixed end is attached to the body, and the fifth free end is positioned at the second distance below the body, the fifth free end being positioned further away from the body than the fifth fixed end, making contact at a fifth loading surface; and
a sixth loading source including a sixth fixed end and a sixth free end, the sixth loading source extending from the sixth fixed end toward the sixth free end, wherein the sixth fixed end is attached to the body, and the sixth free end is positioned the second distance below the body, the sixth free end being positioned further away from the body than the sixth fixed end, making contact at a sixth loading surface, wherein the fifth free end and the sixth free end are positioned at the second distance;
the body has a third opening positioned between the first opening and the second opening of the longitudinal axis of the body;
the fifth loading source extends from the fifth fixed end to the fifth free end into the third opening;
the sixth loading source extends from the sixth fixed end to the sixth free end into the third opening, wherein the fifth free end and the sixth free end extend toward one another;
the fifth loading source is located closer to the first end of the longitudinal axis and the sixth loading source is located closer to the second end of the longitudinal axis; and
the fifth free end and the sixth free end are spaced apart from one another within the third opening such that there is no material disposed longitudinally between.

18. The apparatus of claim 17, wherein the fifth loading source and the sixth loading source apply the second force.

19. The apparatus of claim 18, wherein the body has an exterior perimeter from which six arms extend below the body.

20. The apparatus of claim 19, wherein one of the six arms is positioned at the first end of the longitudinal axis of the body; one of the six arms is positioned at the second end of the longitudinal axis of the body; and four of the six arms are positioned around the exterior perimeter of the body, along the longitudinal axis, equally spaced from one another and the first end and the second end of the longitudinal axis.
